(19) United States
(12) Patent Application Publication
(10) Pub. No.: US 2016/0035987 A1
(43) Pub. Date: Feb. 4, 2016

(54) ORGANIC SEMICONDUCTING BLEND

(71) Applicant: CAMBRIDGE DISPLAY TECHNOLOGY LIMITED, Cambridgeshire (GB)

(72) Inventor: Christopher NEWSOME, St. Ives (GB)

(73) Assignee: Cambridge Display Technology Limited, Godmanchester (GB)

(21) Appl. No.: 14/776,569

(22) PCT Filed: Mar. 12, 2014
(86) PCT No.: PCT/GB2014/050733

§ 371 Date: Sep. 14, 2015

(30) Foreign Application Priority Data
Mar. 14, 2013 (GB) 1304613.1

(51) Int. Cl. H01L 51/00

(52) U.S. Cl. CPC H01L 51/0074; H01L 51/0039; H01L 51/0512

(57) ABSTRACT

A blend for preparing a semiconducting layer an organic electronic device comprises a polymer, a first non-polymeric semiconductor, a second non-polymeric semiconductor and a third non-polymeric semiconductor. The blend enables higher concentration solutions of semiconductor and a broader solution processing window as compared to blends comprising one polymer and one non-polymeric semiconductor. For example, a blend comprising F8-TFB and three different substituted benzothiophene derivatives shows three-fold higher average saturation mobility in OTFTs as compared to a blend of one polymer and one of these benzo thiophene derivatives and consistent peak saturation mobilities after drying at 60° C., 80° C. and 100° C. even after a 2 minute delay.

### FIELD OF THE INVENTION

The present invention relates to a blend and solution for preparing a semiconducting layer of an organic electronic device and to method of preparing a semiconducting layer of an organic electronic device comprising depositing the solution. The invention is also concerned with organic electronic devices comprising the blend and to methods of preparing the devices.

### BACKGROUND

Transistors may be formed by processes wherein their semiconducting layer, and in many cases, other layers is deposited from solution. The resulting transistors are called thin-film transistors. When an organic semiconductor is used in the semiconducting layer, the device is often described as an organic thin film transistor (OTFT).

Various arrangements for OTFTs are known. One device, a top-gate thin-film transistor, comprises source and drain electrodes with a semiconducting layer disposed therebetween in a channel region, a gate electrode disposed over the semiconducting layer and a layer of insulating material disposed between the gate electrode and the semiconductor in the channel region.

The conductivity of the channel can be altered by the application of a voltage at the gate. In this way the transistor can be switched on and off using an applied gate voltage. The drain current that is achievable for a given voltage is dependent on the mobility of the charge carriers in the organic semiconductor in the active region of the transistor, namely the channel region between the source and drain electrodes. Thus in order to achieve high drain currents with low operational voltages, organic thin film transistors must have an organic semiconducting layer which has highly mobile charge carriers in the channel region.

High mobility OTFTs containing small molecule organic semiconductors have been reported and the high mobility has been attributed, at least in part, to the highly crystalline nature of the semiconductor. Particularly high mobilities have been reported in single crystal OTFTs wherein the organic semiconductor is deposited by thermal evaporation (see, for example, Podzorov at al, Appl. Phys. Lett., 2003, 83(17), 3504-3506).

In some instances when using small molecule semiconductors, issues with poor film forming properties can give rise to variations in device performance due to inhomogeneous films. Issues with material reticulation from and adhesion to substrates, film roughness and film thickness variations can limit the performance of small molecule semiconductors in OTFTs. Film roughness can be a further problem for top gate organic thin film transistors as the accumulation layer is formed at the uppermost surface of the semiconducting layer.

To overcome this problem, the use of blends of a small molecule semiconductor and a polymer, especially a polymeric semiconductor, has been developed. The motivation for using such blends is primarily to overcome the poor film forming properties of the small molecule semiconductors in order to obtain a homogeneous film. Blends exhibit superior film forming properties due to the improved film forming properties of the polymer compared to small molecule materials. Numerous examples of small molecule semiconductor and polymeric semiconductor blends can be found in the literature. GB2482974, for example, discloses a blend comprising TFB and a benzothiophene-based small molecule semiconductor.

Blends of a small molecule semiconductor and a polymeric semiconductor may be solution processed, e.g. by spin coating or ink jet printing, to form a semiconducting layer. Generally the process involves dissolving the semiconductors in a solvent, spin coating or ink jet printing the solution onto a substrate and then drying the resulting wet film. During the drying step, the solvent evaporates to yield a film comprising a mixture of the small molecule semiconductor and polymer. Generally an aromatic or substituted aromatic solvent is used to dissolve the semiconductors.

Whilst the use of blends of a small molecule semiconductor and a polymeric semiconductor improves the film forming properties of the small molecule semiconductor, two problems are commonly encountered. First the small molecule semiconductor has limited solubility in the solvents typically used in solution processing. This limits the concentration of total solids that can be dissolved in the solvent which, in turn, limits the thickness of films that can be formed. Lower spin coating speeds and/or reduced spin coating times may be employed to compensate for the low concentration semiconductor solutions in order to attain a target film thickness, but this exacerbates the second problem associated with these blends. As a result, only a limited range of solvents and solution processing conditions may be employed and changes to either can be difficult to make without compromising the solution stability. In other words the processing window of the blends is narrow.

The second problem commonly associated with blends of a small molecule semiconductor and a polymeric semiconductor is that when the blend is deposited on a surface having different surface areas then crystallisation of the small molecule semiconductor is often concentrated in certain of those areas, leaving other areas in which little or no small molecule semiconductor is present, resulting in a film having areas of high and low small molecule organic semiconductor concentration. The difference between different surface areas may be one or more of a difference in surface materials, surface treatments and/or surface energies. In the case of deposition of a small molecule and a polymeric semiconductor blend onto source and drain electrodes and the channel in between them, crystal nucleation centres tend to be concentrated in the region of the electrode surfaces particularly if they have been treated and, if significant crystal growth occurs, large scale segregation can occur. Significant crystal growth can occur perpendicularly to the surface of the treated electrodes and can even protrude from the upper surface of the semiconducting layer. The concentration of crystals in one area inevitably means there is a deficiency of crystals from other areas, e.g. the channel. Thus the overall result is isolated domains of crystalline non-polymeric semiconductor embedded in a polymeric semiconductor overlaying the electrodes and reduced lateral coverage of crystals in the channel region. Higher spinning speeds and/or longer spinning times during solution processing tend to lead to the most significant segregation.

A need therefore exists for blends of small molecule semiconductors and polymeric semiconductors that have a wider processing window and which reliability and consistently yield films having high field effect mobilities due to excellent lateral distribution of small molecule semiconductor therein.

### SUMMARY OF INVENTION

Viewed from a first aspect the present invention provides a blend for preparing a semiconducting layer of an organic electronic device comprising:
(i) a polymer;
(ii) a first non-polymeric semiconductor;
(iii) a second non-polymeric semiconductor; and
(iv) a third non-polymeric semiconductor.

Viewed from a further aspect the present invention provides a method of making a blend as hereinbef ore defined comprising mixing:
(i) a polymer;
(ii) a first non-polymeric semiconductor;
(iii) a second non-polymeric semiconductor; and
(iv) a third non-polymeric semiconductor.

Viewed from a further aspect the present invention provides the use of a blend as hereinbefore defined in the preparation of solution comprising mixing said blend with a solvent.

Viewed from a further aspect the present invention provides a solution comprising a blend as hereinbefore defined and a solvent.

Viewed from a further aspect the present invention provides a method of making a solution as hereinbefore defined comprising mixing:
(i) a polymer;
(ii) a first non-polymeric semiconductor;
(iii) a second non-polymeric semiconductor;
(iv) a third non-polymeric semiconductor; and
(v) a solvent.

Viewed from a further aspect the present invention provides the use of a solution as hereinbefore defined or of a blend as hereinbefore defined in the preparation of a semiconducting layer of an organic electronic device.

Viewed from a further aspect the present invention provides a method for preparing a semiconducting layer of an organic electronic device comprising:
(i) depositing said solution as hereinbefore defined; and
(ii) heating said deposited solution to evaporate said solvent and form said semiconducting layer.

Viewed from a further aspect the present invention provides a method of making an organic electronic device comprising a source electrode and a drain electrode defining a channel region therebetween, an organic semiconducting layer extending across the channel region and in electrical contact with the source and drain electrodes; a gate electrode; and a gate dielectric between the gate electrode and the organic semiconductor layer and the source and drain electrodes, wherein the semiconducting layer is deposited by a method as hereinbefore defined.

Viewed from a further aspect the present invention provides an organic electronic device obtainable by a method as hereinbefore defined.

Viewed from a further aspect the present invention provides an organic electronic device comprising a source electrode and a drain electrode defining a channel region therebetween, an organic semiconducting layer extending across the channel region and in electrical contact with the source and drain electrodes; a gate electrode; and a gate dielectric between the gate electrode and the organic semiconductor layer and the source and drain electrodes, wherein the semiconducting layer comprises a blend as hereinbefore defined.

### DEFINITIONS

As used herein the term “blend” refers to a mixture of at least two compounds and/or polymers. Generally a blend will be a solid, e.g. powder.

As used herein the term “solution” refers to a homogeneous mixture of a compound or blend in a solvent.

As used herein the term “semiconductor” refers to a compound whose conductivity can be modified by temperature, by controlled addition of impurities or by application of electrical fields or light. The term “semiconducting layer” refers to a continuous film of material that is semiconducting. The semiconducting layer formed in the present invention comprises a mixture or blend of polymer and non-polymeric semiconductors. Preferably the polymer forms a matrix in which the non-polymeric semiconductor is dispersed.

As used herein the term “polymer” refers to a compound which has a polydispersity of greater than 1.

As used herein the term “polymeric semiconductor” refers to polymeric compounds comprising repeating units that are semiconductors.

As used herein the term “non-polymeric semiconductor” refers to small molecule compounds that are semiconductors. The term includes dendrimeric and oligomeric compounds (e.g. dimers, trimers, tetramers and pentamers) that have a polydispersity of 1. Preferred non-polymeric semiconductors are crystalline. Preferred non-polymeric semiconductors are organic.

As used herein the term “lateral distribution” refers to a distribution of non-polymeric semiconductor crystals which extend substantially the entire length of the channel between the source and the drain electrodes as well as over the source and drain electrodes, in a direction parallel to the surface of the electrodes and the substrate.

As used herein the term “aromatic solvent” refers to solvents comprising one or more compounds that comprise a planar ring that has 4n+2 pi electrons, wherein n is a zero or a positive integer.

As used herein the term “aromatic ring” refers to a planar ring that has 4n+2 pi electrons, wherein n is a non-negative integer.

As used herein the term “alkyl” refers to saturated, straight chained, branched or cyclic groups. Alkyl groups may be substituted or unsubstituted.

As used herein the term “alkenyl” refers to unsaturated straight chained, branched or cyclic groups. Alkenyl groups may be substituted or unsubstituted.

As used herein the term “alkoxy” refers to O-alkyl groups, wherein alkyl is as defined above.

As used herein the term “amino” refers to primary (i.e. NH₂), secondary (NHR) and tertiary amino groups (NR₂) wherein R is alkyl as defined above.

As used herein the term “amido” refers to groups of the formulae —NHCOR and —NRCOR wherein each R, which may the same or different, is alkyl as defined above.

As used herein the term “silyl” refers to groups of the formulae -A-SiR′R″R′″ wherein A is optionally present and is a saturated or unsaturated group selected from C₁₋₈ alkylene, C₁₋₈ alkenylene or C₁₋₈ alkynylene and each of R′, R″ and R′″ is H or alkyl as defined above.

As used herein the term “stannyl” refers to groups of the formulae —Sn(R′), wherein r is 1, 2 or 3 and each R′ is H or alkyl as defined above.

As used herein the term “halogen” encompasses atoms selected from the group consisting of F, Cl, Br and I.

As used herein, the term “aryl” refers to a group comprising at least one aromatic ring. The term aryl encompasses heteroaryl as well as fused ring systems wherein one or more aromatic ring is fused to a cycloalkyl ring. Aryl groups may be substituted or unsubstituted. An example of an aryl group is phenyl, i.e. C₆H₅. Phenyl groups may be substituted or unsubstituted.

As used herein the term “heteroaryl” refers to aryl groups comprising a heteroatom selected from N, O, S and Se. An example of a heteroaryl group is thiophene, i.e. C₄H₄S. It may be substituted or unsubstituted. A further example is benzothiophene, which has the following structure. It may also be substituted or unsubstituted.

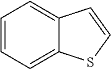

As used herein, the term “cycloalkyl” refers to a saturated or partially saturated mono- or bicyclic alkyl ring system containing 3 to 10 carbon atoms. Cycloalkyl groups may be substituted or unsubstituted.

As used herein the term “fullerene” refers to a compound composed entirely of carbon in the form of a hollow sphere, ellipsoid or tube.

### DESCRIPTION OF THE INVENTION

The blend of the present invention is preferably used for the preparation of a semiconducting layer of an organic electronic device. The blend of the present invention advantageously enables higher concentration solutions of semiconductor to be prepared than blends solely comprising a polymer, e.g. a polymeric semiconductor, and one non-polymeric semiconductor. This is highly beneficial as it broadens the solution processing window of the blends, e.g. it enables them to be processed in a wider range of film deposition conditions without impacting on the electrical performance of the semiconducting layer.

The blend of the present invention comprises:
(i) a polymer, e.g. a polymeric semiconductor;
(ii) a first non-polymeric semiconductor;
(iii) a second non-polymeric semiconductor; and
(iv) a third non-polymeric semiconductor.

The first, second and third non-polymeric semiconductors are different. Preferably the first, second and third non-polymeric semiconductors are organic. Preferred blends of the present invention comprise three different non-polymeric semiconductors.

In a preferred blend of the present invention the second non-polymeric semiconductor has a higher molecular weight than the first non-polymeric semiconductor. In a further preferred blend, the third non-polymeric semiconductor has a higher molecular weight than the second non-polymeric semiconductor.

More preferably the third non-polymeric semiconductor has a molecular weight which is at least 56 amu higher than the first non-polymeric semiconductor. Still more preferably the third non-polymeric semiconductor has a molecular weight which is 56 to 180 amu, more preferably 70 to 140 amu and still more preferably 84 to 112 amu higher than the first non-polymeric semiconductor.

More preferably the second non-polymeric semiconductor has a molecular weight which is at least 28 amu higher than the first non-polymeric semiconductor. Still more preferably the second non-polymeric semiconductor has a molecular weight which is 28 to 70 amu and more preferably 42 to 56 amu higher than the first non-polymeric semiconductor.

More preferably the third non-polymeric semiconductor has a molecular weight which is at least 14 amu higher than the second non-polymeric semiconductor. Still more preferably the third non-polymeric semiconductor has a molecular weight which is 14 to 140 amu higher, more preferably 28 to 84 amu and still more preferably 28 to 56 amu higher that the second non-polymeric semiconductor.

The non-polymeric semiconductors present in the blends of the present invention preferably comprise a core of at least three fused rings wherein each ring is independently selected from aromatic rings and heteroaromatic rings that are each individually unsubstituted or substituted with one or more substituents. Exemplary substituents include C₁₋₁₂ alkyl groups, C₁₋₁₂ alkoxy groups, halogens (e.g. F), or silyl groups including trialkylsilyl and trialkylsilylethynyl. Preferably the cores of the first, second and third non-polymeric semiconductors are identical.

Preferably the first, second and third non-polymeric semiconductors are each a a benzothiophene derivative and more preferably a benzothiophene derivative of formula (I):

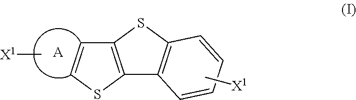

wherein A is a phenyl group or a thiophene group, said phenyl group or thiophene group optionally being fused with a phenyl group or a thiophene group which can be unsubstituted or substituted with at least one group of formula X¹ and/or fused with a group selected from a phenyl group, a thiophene group and a benzothiophene group, any of said phenyl, thiophene and benzothiphene groups being unsubstituted or substituted with at least one group of formula X¹; and
each group X¹ may be the same or different and is selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups, unsubstituted or substituted alkenyl groups having from 2 to 12 carbon atoms and unsubstituted or substituted alkynyl groups having from 2 to 12 carbon atoms, or (ii) a polymerisable or reactive group selected from the group consisting of halogens, boronic acids, diboronic acids and esters of boronic acids and diboronic acids, alkenyl groups having from 2 to 12 carbon atoms and stannyl groups.

Examples of alkyl groups include methyl, ethyl, propyl, butyl, pentyl, hexyl, heptyl, octyl, nonyl or decyl. Examples of alkoxy groups include methoxy, ethoxy, propoxy, isopropoxy and butoxy. Examples of amino groups include amino, methylamino, ethylamino and methylethylamino. Examples of silyl groups include trialkylsilyl and trialkylsilylethynyl. Examples of alkenyl groups include ethenyl, propenyl and 2-methylpropenyl.

Possible substituents on the afore-mentioned X¹ groups include alkoxy groups having from 1 to 12 carbon atoms, halogen atoms, amino groups that may be unsubstituted or substituted with one or two alkyl groups that may be the same or different and each having from 1 to 8 carbon atoms, acylamino groups having from 2 to 12 carbon atoms, nitro groups, alkoxycarbonyl groups having from 2 to 7 carbon atoms, carboxyl groups, aryl groups having from 5 to 14 carbon atoms and 5- to 7-membered heteroaryl groups containing from 1 to 3 sulfur atoms, oxygen atoms, selenium atoms and/or nitrogen atoms.

In preferred benzothiophene derivatives of formula (I) A is selected from:
a thiophene group that is fused with a phenyl group substituted with at least one group of formula X¹; or
a phenyl group that may be unsubstituted or substituted with at least one group of formula X¹, said phenyl group further optionally being fused with a thiophene group which can be unsubstituted or substituted with at least one group of formula X¹ and/or fused with a benzothiophene group, said benzothiphene group being unsubstituted or substituted with at least one group of formula X¹.

In particularly preferred benzothiophene derivatives A is a thiophene group that is fused with a phenyl group substituted with at least one group of formula X¹.

Examples of preferred non-polymeric semiconductors are shown below:

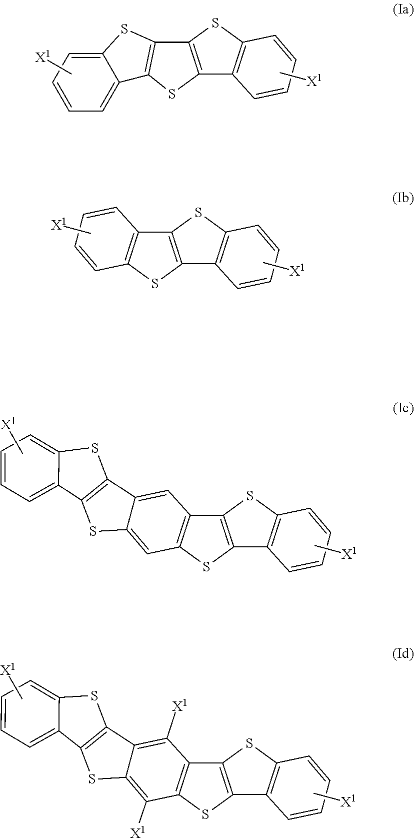

wherein X¹ is as defined above in relation to formulae (I). More preferably each of said first, second and third non-polymeric semiconductors are of formula (Ia):

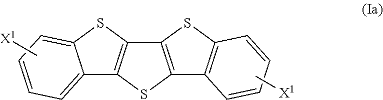

wherein each group X¹ may be the same or different and is selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms. Still more preferably each of said first, second and third non-polymeric semiconductors are of formula (Iai):

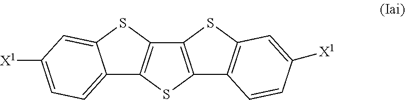

wherein each group X may be the same or different and is selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms.

Preferably each of said first, second and third non-polymeric semiconductors are of formula (lai), wherein within each non-polymeric semiconductor each group X¹ is identical.

In preferred non-polymeric semiconductors of formula (Ia) or (Iai), especially (Iai), each group X¹ is an unsubstituted or substituted straight, branched or cyclic alkyl groups having from 1 to 20 carbon atoms. Still more preferably each group X¹ is a straight alkyl group. Yet more preferably each group X¹ is an unsubstituted alkyl group. Alkyl group comprises 1 to 16 carbon atoms, and more preferably 2 to 12 carbon atoms are preferred.

Particularly preferably each of said first, second and third non-polymeric semiconductors are of formula (Ia) or (Iai), especially (Iai), wherein each group X¹ is a group of the formula CₙH₂ₙ₊₁ wherein n is an integer between 1 and 16. Still more preferably each of said first, second and third non-polymeric semiconductors are of formula (Ia) or (Iai), especially (Iai), wherein within each non-polymeric semiconductor each group X¹ is identical and is a group of the formula CₙH₂ₙ₊₁ wherein n is an integer between 1 and 16.

As stated above, the first, second and third non-polymeric semiconductors present in the blend of the present invention are different. Thus in preferred blends of the present invention the first non-polymeric semiconductor is a compound of formula (Ia) or (Iai), especially (Iai), wherein each X¹ is a group of the formula CₙH₂ₙ₊₁ wherein n is the lowest integer, herein n(I), relative to the X¹ groups present in the second and third non-polymeric semiconductors. In further preferred blends of the present invention the third non-polymeric semiconductor is a compound of formula (Ia) or (Iai), especially (Iai), wherein each X¹ is a group of the formula CₙH₂ₙ₊₁ wherein n is the highest integer, herein n(h), relative to the X¹ groups present in the first and second non-polymeric semiconductors. In further preferred blends of the present invention the second non-polymeric semiconductor is a compound of formula (Ia) or (Iai), especially (Iai), wherein each X is a group of the formula CₙH₂ₙ₊₁ wherein n is a middle integer, herein n(m), relative to the X¹ groups present in the first and third non-polymeric semiconductors. In particularly preferred blends of the present invention, the difference between n(l) and n(h) is at least 4, more preferably 4, 5, 6, 7 or 8 and still more preferably 6, 7 or 8, e.g. 6. In further particularly preferred blends of the present invention the difference between n(l) and n(m) is at least 2, more preferably 2, 3, 4 or 5 and still more preferably 3 or 4, e.g. 4. In further particularly preferred blends of the present invention the difference between n(m) and n(h) is at least 1, more preferably 1, 2, 3 or 4 and still more preferably 2 or 3, e.g. 2.

In particularly preferred blends of the present invention, each group X¹ in the first non-polymeric semiconductor is a group of formula CₙH₂ₙ₊₁ wherein n is an integer between 1 and 5. In further particularly preferred blends each group X¹ in the third non-polymeric semiconductor is a group of formula CₙH₂ₙ₊₁ wherein n is an integer between 7 and 12.

In further particularly preferred blends the second non-polymeric semiconductor is:

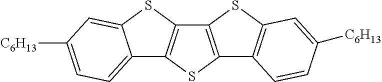

In still further preferred blends the first non-polymeric semiconductor is selected from:

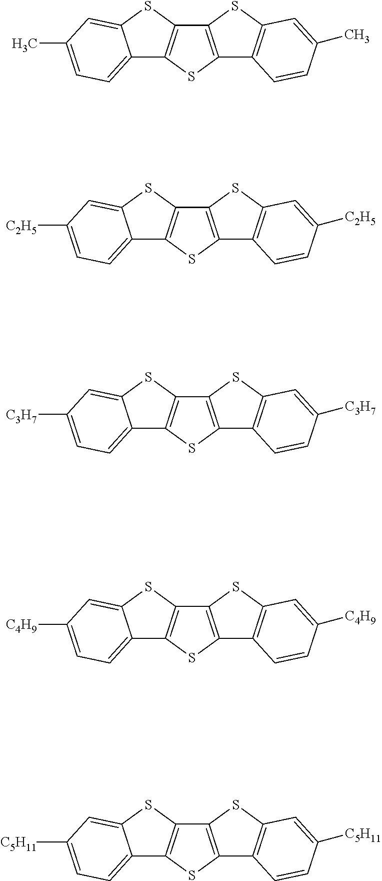

Particularly preferably the first non-polymeric semiconductor is:

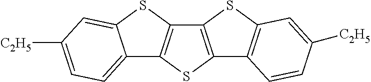 [SMILES: CCc1ccc2c(c1)sc1c2sc2c3ccc(CC)cc3sc21]

In still further preferred blends the third non-polymeric semiconductor is selected from:

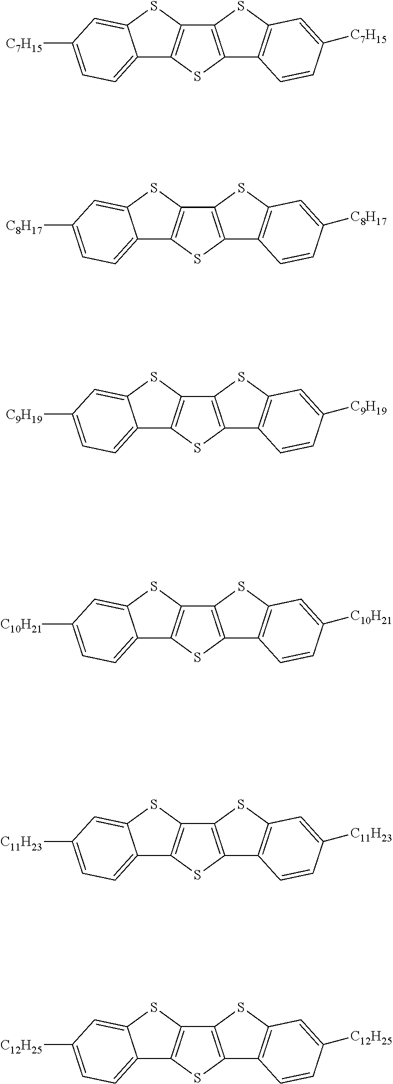

Particularly preferably the third non-polymeric semiconductor is:

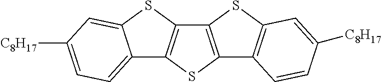

In an especially preferred blend of the present invention the first non-polymeric semiconductor is:

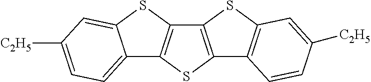 [SMILES: CCc1ccc2c(c1)sc1c2sc2c3ccc(CC)cc3sc21]

the second non-polymeric semiconductor is:

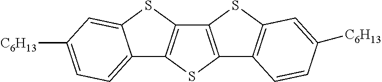

and the third non-polymeric semiconductor is:

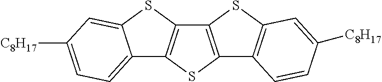

Suitable non-polymeric semiconductors for use in the blends of the invention may be prepared by conventional techniques.

Preferred blends of the present invention consist essen ially of (e.g. consist of)
(i) a polymer, e.g. a polymeric semiconductor;
(ii) a first non-polymeric semiconductor;
(iii) a second non--polymeric semiconductor; and
(iv) a third non-polymeric semiconductor.

In preferred blends of the present invention the weight ratio of the first non-polymeric semiconductor to the second non-polymeric semiconductor is in the range 1:5 to 1:20 and more preferably 1:6 to 1:9, e.g. about 1:8. In further preferred blends the weight ratio of the second non-polymeric semiconductor to the third non-polymeric semiconductor is in the range 8:1 to 2:1 and more preferably 6:1 to 3:1, e.g. about 4:1. In further preferred blends the weight ratio of the first non-polymeric semiconductor to the third non-polymeric semiconductor is in the range 1:1 to 1:4, e.g. about 1:2. In further preferred blends the weight ratio of the first, second and third non-polymeric semiconductors is (1:1.5:4) to (1:4:10).

The blend of the present invention comprises a polymer, preferably a polymeric semiconductor. The polymeric semiconductor present in the solution or blend for deposition may be any known polymeric semiconductor suitable for processing from solution. Examples of polymeric semiconductors known to the skilled person are described in prior art such as Smith et. al., Applied Physics Letters, Vol 93, 253301 (2008); Russell et. al., Applied Physics Letters, Vol 87, 222109 (2005); Ohe et. al., Applied Physics Letters, Vol 93, 053303 (2008); Madec et. al., Journal of Surface Science & Nanotechnology, Vol 7, 455-458 (2009); and Kang et. al., J. Am. Chem, Soc., Vol 130, 1227375 (2008).

Suitable polymeric semiconductors are commercially available.

Preferably the polymeric semiconductor is a conjugated polymer. Preferably the polymeric semiconductor comprises a repeat unit of formula (II)

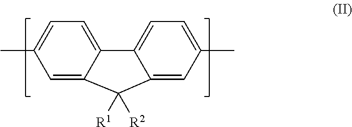

wherein R¹ and R² are the same or different and each is selected from the group consisting of hydrogen, an alkyl group having from 1 to 16 carbon atoms, an aryl group having from 5 to 14 carbon atoms and a 5- to 7-membered heteroaryl group containing from 1 to 3 sulfur atoms, oxygen atoms, nitrogen atoms and/or selenium atoms, said aryl group or heteroaryl group being unsubstituted or substituted with one or more substituents selected from an alkyl group having from 1 to 16 carbon atoms and an alkoxy group having from 1 to 16 carbon atoms.

Examples of alkyl groups include methyl, ethyl, propyl, butyl, pentyl, hexyl, heptyl, octyl, nonyl or decyl. Examples of aryl groups include phenyl, indenyl, naphthyl, phenanthrenyl and anthracenyl groups. Examples of 5- to 7-membered heteroaryl groups include furyl, thienyl, pyrrolyl, azepinyl, pyrazolyl, imidazolyl, oxazolyl, isoxazolyl, thiazolyl, isothiazolyl, 1,2,3-oxadiazolyl, triazolyl, tetrazolyl, thiadiazolyl, pyranyl, pyridyl, pyridazinyl, pyrimidinyl and pyrazinyl groups. Examples of alkoxy groups include methoxy, ethoxy, propoxy, isopropoxy and butoxy.

In preferred polymeric semiconductors R¹ and R² are the same.

Preferred polymeric semiconductors comprise a repeat unit of formula (II) wherein, wherein R¹ and R² are each selected from the group consisting of hydrogen, an alkyl group having from 1 to 12 carbon atoms and a phenyl group, said phenyl group being unsubstituted or substituted with one or more substituents selected from an alkyl group having from 1 to 12 carbon atoms and an alkoxy group having from 1 to 12 carbon atoms. Still more preferred polymeric semiconductors comprise a repeat unit of formula (II) wherein R¹ and R² are each selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms. Yet further preferred polymeric semiconductors comprise a repeat unit of formula (II) wherein R¹ and R² are each selected from the group consisting of an alkyl group having from 4 to 12 carbon atoms, preferably butyl, pentyl, hexyl, heptyl, octyl, nonyl or decyl, particularly octyl, e.g. n-ocytyl.

Further preferred semiconducting polymers comprise a repeat unit of formula (III):

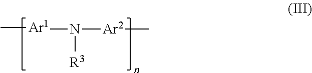

wherein Ar¹ and Ar² are the same or different and each is selected from an aryl group having from 5 to 14 carbon atoms and a 5- to 7-membered heteroaryl group containing from 1 to 3 sulfur atoms, oxygen atoms, nitrogen atoms and/or selenium atoms, said aryl group or heteroaryl group being unsubstituted or substituted with one or more substituents selected from an alkyl group having from 1 to 16 carbon atoms and an alkoxy group having from 1 to 16 carbon atoms;
R³ is an alkyl group having from 1 to 8 carbon atoms or a phenyl group which may be unsubstituted or substituted with an alkyl group having from 1 to 8 carbon atoms;
and n is an integer greater than or equal to 1, preferably 1 or 2.

Examples of aryl groups include phenyl, indenyl, naphthyl, phenanthrenyl and anthracenyl groups. Examples of 5- to 7-membered heteroaryl groups include furyl, thienyl, pyrrolyl, azepinyl, pyrazolyl, imidazolyl, oxazolyl, isoxazolyl, thiazolyl, isothiazolyl, 1,2,3-oxadiazolyl, triazolyl, tetrazolyl, thiadiazolyl, pyranyl, pyridyl, pyridazinyl, pyrimidinyl and pyrazinyl groups. Examples of alkyl groups include methyl, ethyl, propyl, butyl, pentyl, hexyl, heptyl, octyl, nonyl or decyl. Examples of alkoxy groups include methoxy, ethoxy, propoxy, isopropoxy and butoxy.

In preferred polymeric semiconductors comprising a repeat unit of formula (III) Ar¹ and Ar² are the same. Particularly preferably each of Ar¹ and Ar² is a phenyl group, preferably an unsubstituted phenyl group.

In further preferred polymeric semiconductors comprising a repeat unit of formula (III) R³ is an alkyl group having from 1 to 8 carbon atoms or a phenyl group which may be unsubstituted or substituted with an alkyl group having from 1 to 8 carbon atoms. Particularly preferably R³ is alkyl group, especially an alkyl group comprising 2 to 5 carbon atoms, e.g. ethyl, propyl, butyl, pentyl. Still more preferably R³ is a phenyl group substituted with an alkyl group having from 1 to 8 carbon atoms, e. g. ethyl, propyl, butyl, pentyl.

Still more preferably the polymeric semiconductor present in the blend of the present invention comprises a repeat unit of formula (II) and a repeat unit of formula (III). Preferably the ratio of repeat unit of formula (II) to formula (III) is in the range 3:1 to 1:3, more preferably 2:1 to 1:2 and still more preferably about 1:1. Particularly preferably the polymeric semiconductor comprises a repeat unit of formula (IV):

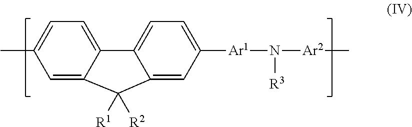

wherein R¹, R², Ar¹, Ar² and R³ are as defined above in relation to formulae (II) and (III).

Yet more preferably the polymeric semiconductor is TFB [9,9′-dioctylfluorene-co-N-(4-butylphenyl)-diphenylamine]n, wherein n is greater than 100. Alternatively the polymeric semiconductor is PFB [(9,9-dioctylfluorene-co-bis-N,N-(4-butylphenyl)-bis-N,N-phenyl-1,4-phenylenediamine)n, wherein n is greater than 100

Preferably the weight ratio of the polymeric to non-polymeric semiconductor in the semiconducting layer is in the range 60:40 to 90:10, more preferably 70:30 to 85:15 and still more preferably about 75:25.

The blend of the present invention can be made by mixing the polymer, e.g. polymeric semiconductor, the first non-polymeric semiconductor, the second non-polymeric semiconductor and the third non-polymeric semiconductor, e.g. by stirring or shaking.

The blends of the present invention are particularly useful in the preparation of a solution for preparing a semiconducting layer of an organic electronic device such as a thin film transistor where a higher mobility material than the host polymer is required. The use of a blend of the present invention in the preparation of solution advantageously enables solutions with a higher total solids weight concentration to be obtained. The use of a blend comprising more than one non-polymeric semiconductor also beneficially widens the processing window of the resulting solution in solution processing techniques.

The solutions of the present invention comprise a blend as hereinbefore described and a solvent. Preferred blends for incorporation into the solution are those blends that are described as preferred above.

Preferably the solvent present in the solution is aromatic. Preferably the aromatic solvent is selected from a substituted benzene, a substituted naphthalene, a substituted tetrahydronaphthalene or a substituted or unsubstituted C₅₋₈ cycloalkylbenzene. Suitable aromatic solvents are commercially available from a range of suppliers. Anhydrous grade solvents are typically selected. Such solvents are generally able to form solutions of both polymeric and non-polymeric semiconductors.

Preferably the aromatic solvent is of formula (Va), (Vb), (Vc) or (Vd):

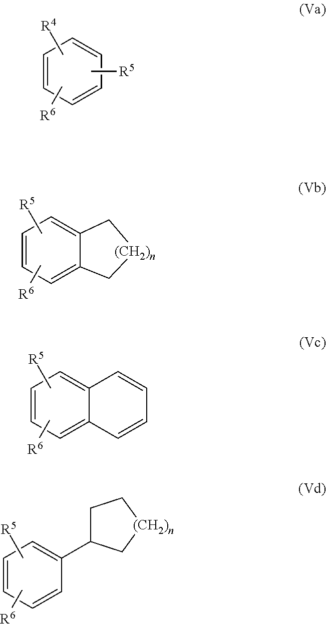

wherein
R⁴ is selected from C₁₋₆ alkyl, OC₁₋₆ alkyl, or C(O)OC₁₋₆ alkyl; and
R⁵ and R⁶ are each independently selected from H, C₁₋₆ alkyl, OC₁₋₆ alkyl or C(O)OC₁₋₆ alkyl; and
n is 1, 2 or 3

In some preferred solvents of formula (Va) R⁴ is C₁₋₆ alkyl. In further preferred solvents R⁵ is H. In still further preferred solvents R⁶ is C₁₋₆ alkyl, preferably methyl. Yet more preferably R⁴ is C₁₋₆ alkyl, preferably methyl, R⁵ is H and R⁶ is C₁₋₆ alkyl.

In other preferred aromatic solvents of formula (Va), R⁴ is OC₁₋₆ alkyl, particularly methoxy (OMe) or ethoxy (OEt). In further preferred solvents, R⁵ is H, C₁₋₆ alkyl (e.g. methyl or ethyl) or OC₁₋₆ alkyl (e.g. methoxy or ethoxy). In still further preferred solvents R⁶ is H. Particularly preferably R⁴ is OC₁₋₆ alkyl, e.g. OMe or OEt, R⁵ is C₁₋₆ alkyl, e.g. methyl or ethyl and R⁶ is H or R⁴ is OC₁₋₆ alkyl, e.g. OMe or OEt, R⁵ is H and R⁶.

In other preferred aromatic solvents R⁴ is C(O)OC₁₋₆ alkyl, particularly C(O)OMe or C(O)OEt. In further preferred solvents R⁵ is H or C₁₋₆ alkyl (e.g. methyl or ethyl). In still further preferred solvents R⁶ is H. Particularly preferably R⁴ is C(O)OC₁₋₆ alkyl, e.g. C(O)OMe or C(O)OEt, R⁵ is H and R⁶ is H.

In preferred aromatic solvents of formula (Vb), n is 1 or 2, particularly 2. In particularly preferred solvents, at least one of R⁵ and R⁶ is H. Still more preferably, both of R⁵ and R⁶ are H.

In preferred aromatic solvents of formula (Vc), at least one of R⁵ and R⁶ is C₁₋₆ alkyl. In further preferred solvents of formula (Vc) R⁵ is H. In still further preferred solvents R⁶ is C₁₋₆ alkyl, preferably methyl. Yet more preferably R⁵ is H and R⁶ is C₁₋₆ alkyl, preferably methyl.

In preferred aromatic solvents of formula (Vd), n is 1 or 2, particularly 2. In particularly preferred solvents, at least one of R⁵ and R⁶ is H. Still more preferably, both of R⁵ and R⁶ are H.

When the aromatic solvent is disubstituted, the substituents may be present in a [1,2], [1,3] or [1,4] substitution pattern. Preferably, however, the substituents are present in a [1,2] or ortho pattern. When the aromatic solvent is trisubstituted, the substituents are preferably present in a [1,3,5] substitution pattern.

Preferably the aromatic solvent is selected from the group consisting of toluene, o-xylene, m-xylene, p-xylene, anisole (or methoxybenzene), mesitylene, ethoxybenzene, 2-methylanisole, 3-methylanisole, 4-methylanisole, 1-ethoxy-2-methylbenzene, 1-ethoxy-3-methylbenzene, 1-ethoxy-4-methylbenzene, acetophenone, tetralin, 1,2-dimethoxybenzene, 1,3-dimethoxybenzene, 1,4-dimethoxybenzene, 1-methoxy-2-ethoxybenzene, 1-methoxy-3-ethoxybenzene, 1-methoxy-4-ethoxybenzene, ethyl benzoate, 1,2-diethoxybenzene, 2-methyl acetophenone, 3-methylacetophenone, 4-methylacetophenone, 2-ethylacetophenone, 3-ethylacetophenone, 4-ethylacetophenone, 1,3-diethoxybenzene, 1,4-diethoxybenzene, 2-methoxyacetophenone, 3-methoxyacetophenone, 4-methoxyacetophenone, ethyl 2-methylbenzoate, ethyl 3-methylbenzoate, ethyl 4-methylbenzoate, ethyl 2-ethylbenzoate, ethyl 3-ethylbenzoate, ethyl 4-ethylbenzoate, 1-methylnaphthalene and cyclohexylbenzene. Particularly preferably the aromatic solvent is selected from the group consisting of of toluene, o-xylene, m-xylene, p-xylene, anisole (or methoxybenzene), mesitylene and tetralin.

As mentioned above, an advantage of the blend of the present invention is that solutions having a higher total solids (i.e. total weight of polymer and non-polymeric semiconductor) concentration may be obtained. This is highly advantageous as it provides the solution with a broader processing window, e.g. the solution can be spin coated at higher spin speeds, for a longer duration of time, dried under varying conditions in order to obtain a target film thickness.

In preferred solutions of the present invention the total concentration of solids in the solvent is at least 1.0% w/v and more preferably at least 1.5% w/v. More preferably the total concentration of solids in the solvent is 1.5 to 3% w/v and still more preferably it is 1.6 to 2.5 w/v. When the solvent is o-xylene, the total concentration of solids is preferably about 1.6% w/v. When the solvent is tetralin, the total concentration of solids is preferably about 1.8 % w/v.

The solutions of the present invention may be prepared by conventional methods. Thus preferably the solutions are prepared by mixing (e.g. stirring or shaking) a blend as hereinbef ore defined and a solvent. Alternatively the solution may be prepared by mixing each of the components of the blend individually into a solvent. Heating of the solution may be required in order to ensure full dissolution of the solid into the solvent.

The blend and solution of the present invention are particulary useful in the preparation of a semiconducting layer of an organic electronic device. The use of the blend and solution of the present invention enables semiconducting layers of high mobility to be prepared under a range of processing conditions.

The method comprises depositing a solution as hereinbefore defined and heating the deposited solution to evaporate said solvent and form said semiconducting layer. Preferred solutions for use in the method are those that are described above as preferred.

Deposition of the semiconducting layer is preferably carried out by solution processing. Any conventional solution-based processing method may be used. Representative examples of solution-based processing methods include spin coating, dip coating, slot die coating, doctor blade coating, ink-jet printing, flexographic and gravure printing. In preferred methods of the invention, however, film deposition is carried out by spin coating.

The parameters used for spin coating the semiconductor film such as spin coating speed, acceleration and time are selected on the basis of the target thickness for the semiconducting layer. As mentioned above, an advantage of the solutions of the invention is that a broader range of spin coating conditions may be used. Preferably the spin speed is 400 to 4000 rpm, more preferably 400 to 3000 rpm and still more preferably 400 to 2000 rpm. Preferably the spin time is 10 to 100 seconds, more preferably 15 to 60 seconds and still more preferably 30 to 60 seconds. Preferably the acceleration time from rest is less than 10 seconds, preferably less than 5 seconds and still more preferably less than 3 seconds. Any conventional spin coating apparatus may be used. The apparatus is used in a conventional manner.

Heating of the deposited solution to form the semiconducting layer is preferably carried out on a hot plate. The heating step causes the solvent present in the solution to evaporate. Preferably the temperature of the hot plate in the heating step is 75 to 250° C., more preferably 80 to 150° C. and still more preferably 90 to 120° C. Preferably the heating time is 15 to 180 seconds, more preferably 30 to 120 seconds and still more preferably 45 to 90 seconds. Any conventional heating apparatus, e.g. hot plate, convection oven, vacuum assisted drying, may be used. The apparatus is used in a conventional manner.

Heating may be carried out immediately after deposition or may be delayed. Advantageously this does not impact on the electrical performance of the semiconducting layers obtained.

Preferably the thickness of the semiconducting layer is 5 to 200 nm, more preferably 10 to 100 nm and still more preferably 20 to 70 nm.

The blends and solutions of the present invention are particularly advantageous when the semiconducting layer is deposited over at least a portion of source and drain electrodes and in a channel region located in between, particularly when the source and drain electrodes have been pre-treated with a surface modifying compound, e.g. a fluorinated benzenethiol or electron acceptor material such as fluorinated fullerene. Such pre-treatments are carried out to reduce the contact resistance of the devices through an increase in the work function of the metal contact and reduced barrier for charge injection. A drawback of the treatments such as fluorinated benzenethiols, however, is that the resultant treated electrode surfaces tend to disrupt the lateral distribution of the non-polymeric semiconductor. Crystal nucleation centres tend to be concentrated in the region of the treated electrode surfaces and, if significant crystal growth occurs, large scale segregation can occur leading to regions void of non-polymeric semiconductor and therefore electrical properties mostly attributed to the lower mobility polymeric component. Significant crystal growth can occur perpendicularly to the surface of the treated electrodes and can even protrude from the upper surface of the semiconducting layer. The concentration of crystals in one area inevitably means there is a deficiency of crystals from other areas. Thus the overall result is isolated domains of crystalline non-polymeric semiconductor embedded in a polymeric semiconductor overlaying the electrodes and reduced lateral coverage of crystals in the channel region.

The presence of a mixture of non-polymeric semiconductors in the blends and solutions of the present invention suppresses crystallisation during the deposition step so crystallisation occurs rapidly and homogeneously during the heating step. It thereby extends over both of the source and drain electrodes as well as the channel region. As a result devices comprising the semiconducting layer have high mobilities and low contact resistance.

In the methods of the present invention the solution or blend is deposited over at least a portion of source and drain electrodes and in a channel region located in between the electrodes. Optionally the method of the invention comprises a step of binding a self-assembled monolayer (SAM) to the surface of the channel region prior to the deposition of the semiconductor film. When present the SAM should act to reduce the polarity of the surface of the channel region whilst remaining as a wetting surface for the semiconductor solution. Substrate anchoring groups of the SAM such silane or silazane are preferable for glass, with terminal groups such as phenyl or naphtylene.

In preferred methods of the invention at least a part of one surface, more preferably at least one surface, of each of the electrodes is coated with a surface-modifying compound. The surface modifying compound preferably reduces contact resistance between the semiconductors and the electrodes, and therefore a reduced barrier for charge injection, by altering the work function of the source and drain electrodes.

Preferably the surface-modifying compound is a partially fluorinated fullerene. The fullerene of the partially fluorinated fullerene may be any carbon allotrope in the form of a hollow sphere or ellipsoid. The fullerene preferably consists of carbon atoms arranged in 5, 6 and/or 7 membered rings, preferably 5 and/or 6 membered rings. C₆₀ Buckminster Fullerene is particularly preferred.

The partially fluorinated fullerene preferably has formula CₐF_{b} wherein b is in the range of 10-60, optionally 10-50, and a is more than b, e.g. a is 40 to 90, more preferably 50 to 70. Examples include C₆₀F₁₈, C₆₀F₂₀, C₆₀F₃₆, C₆₀F₄₈, C₇₀F₄₄, C₇₀F₄₆, C₇₀F₄₈, and C₇₀F₅₄. Partially fluorinated fullerenes and their synthesis are described in more detail in, for example, Andreas Hirsch and Michael Brettreich, “Fullerenes: Chemistry and Reactions”, 2005 Wiley-VCH Verlag GmbH & Co KGaA, “The Chemistry Of Fullerenes”, Roger Taylor (editor) Advanced Series in Fullerenes—Vol. 4 and “Chemical Communications, 1996(4), 529-530. The partially fluorinated fullerene may consist of carbon and fluorine only or may include other elements, for example halogens other than fluorine and/or oxygen.

The partially fluorinated fullerene preferably has a lowest unoccupied molecular orbital (LUMO) level in the range of about −4.0 or deeper, optionally −4.0 to −5.0 eV as measured, e.g. at room temperature, by cyclic voltammetry relative to a Saturated Calomel Electrode (SCE) in acetonitrile using tetraethylammonium perchlorate as supporting electrolyte, and assuming the Fermi energy level of SCE as 4.94 eV.

Surface treatment methods for modification of the work function of the source and/or drain contacts are preferably carried out by dissolution or dispersion of the surface-modifying compound into a carrier solvent and immersion of the substrates into the resulting solution or dispersion. Preferably the substrates are then removed from the solution or dispersion and rinsed in fresh carrier solvent to remove any excess, non-bound compound. By use of a solution processing method in which the source and drain electrodes are immersed in a solution of the partially fluorinated fullerene, it may be possible to coat all exposed faces of the source and drain electrodes. In particular, faces of the source and/or drain electrodes that face the channel may be coated.

Suitable solvents for partially fluorinated fullerenes include benzenes and naphthalenes substituted with one or more substituents selected from: halogen, for example chlorine; C₁₋₁₀ alkyl, for example methyl; and C₁₋₁₀ alkoxy, for example methoxy. Exemplary solvents include mono- or poly-chlorinated benzenes or naphthalenes, for example dichlorobenzene and 1-chloronaphthalene; benzene or naphthalene substituted with one or more methyl groups, for example toluene, o-xylene, m-xylene, 1-methylnaphthalene; and solvents substituted with more than one of a halogen, C₁₋₁₀ alkyl and C₁₋₁₀ alkoxy, for example 4-methylanisole. A single solvent or a mixture of more than one solvent may be used to deposit a partially fluorinated fullerene.

The thickness of the surface modification layer, e.g. partially fluorinated fullerene layer, is preferably no more than 10 nm and optionally less than 5 nm. Preferably the surface modification layer is a bound or adsorbed layer. In some cases the surface modification layer may be in part, or in total, a monolayer.

The semiconducting layer may be incorporated into any organic electronic device that benefits from improved mobility. Preferably, however, the organic electronic device is an organic thin film transistor. The transistors may be p-type or n-type, but are preferably p-type. Suitable transistor configurations include top-gate transistors and bottom-gate transistors.

An organic electronic device of the present invention comprises a source electrode and a drain electrode defining a channel region therebetween, an organic semiconducting layer extending across the channel region and in electrical contact with the source and drain electrodes; a gate electrode; and a gate dielectric between the gate electrode and the organic semiconducting layer and the source and drain electrodes, wherein the semiconducting layer comprises a blend as hereinbefore defined. The device is preferably an organic thin-film transistor, e.g. a top gate thin film transistor.

A preferred device of the invention comprises:
i) a substrate;
ii) source and drain electrodes deposited on said substrate and having a channel region located in between them;
iii) a semiconducting layer deposited over at least a portion of said source and drain electrodes and in said channel region;
iv) an insulating layer deposited over said semiconducting layer; and
v) a gate electrode deposited on said insulating layer,
wherein said semiconducting layer comprises a blend as hereinbefore defined.

A further preferred device of the invention comprises:
i) a substrate;
ii) a gate electrode deposited on said substrate;
iii) an insulating layer deposited over said gate electrode;
iv) source and drain electrodes deposited over said insulating layer and having a channel region located in between them;
v) a semiconducting layer deposited over at least a portion of said source and drain electrodes and in said channel region;
wherein said semiconducting layer comprises a blend as hereinbefore defined.

The present invention also relates to a method of making an organic thin-film transistor comprising a source electrode and a drain electrode defining a channel region therebetween, an organic semiconducting layer extending across the channel region and in electrical contact with the source and drain electrodes; a gate electrode; and agate dielectric between the gate electrode and the organic semiconductor layer and the source and drain electrodes, wherein the semiconducting layer is deposited by solution-based processing methods (e.g. spin coating, dip coating, slot die coating, doctor blade coating, ink-jet printing, flexographic and gravure printing).

In one preferred method the transistor is a top gate transistor. In such methods the source and drain electrodes having a channel region located in between them are preferably deposited on a substrate, and the semiconducting layer is deposited over at least a portion of the source and drain electrodes and in said channel region. Preferably at least a part of one surface, more preferably at least one surface, of each of the electrodes is pre-coated with a surface-modifying compound as described above. Preferably the method further comprises depositing an insulating layer on the surface of the semiconducting layer. Still more preferably the method further comprises depositing a gate electrode on the insulating layer.

A preferred method of making a top gate thin film transistor therefore comprises:
(i) depositing source and drain electrodes having a channel region located in between them on a substrate;
(ii) optionally treating at least a part of at least one surface of said electrodes with a surface-modifying compound;
(iii) depositing a semiconducting layer over at least a portion of the source and drain electrodes and in said channel region according to the solution processing methods hereinbefore described;
(iv) depositing an insulating layer on the surface of the semiconducting layer; and
(v) depositing a gate electrode on the insulating layer.

In another preferred method the transistor is a bottom gate transistor. In such methods the source and drain electrodes having a channel region located in between them are deposited on a substrate on which a gate electrode and an insulating layer have already been deposited, and the semiconducting layer is deposited over at least a portion of the source and drain electrodes and in the channel region. Preferably at least a part of at least one surface, more preferably at least one surface, of each of the electrodes is coated with a surface-modifying compound as described above.

A preferred method of making a bottom gate thin film transistor therefore comprises:
(i) depositing agate electrode on a substrate;
(ii) depositing an insulating layer on the surface of the gate electrode;
(iii) depositing source and drain electrodes having a channel region located in between them on the insulating layer;
(iv) optionally treating at least apart of at least one surface of said electrodes a surface-modifying compound; and
(v) depositing a semiconducting layer over at least a portion of the source and drain electrodes and in said channel region according to the method hereinbefore described.

The electrodes (source, drain and gate) are preferably deposited by thermal evaporation. The electrodes are preferably 20 to 300 nm thick and more preferably 40 to 100 nm. The insulating layer is preferably deposited by spin coating. The insulating layer is preferably 10 to 2000 nm thick and more preferably 10 to 400 nm. The surface-modifying compound is preferably deposited by immersion.

The substrate may be any material conventionally used in the art such as glass or plastic (e.g. of PEN or PET type). Optionally the substrate is pre-treated to improve adhesion thereto.

The source, drain and gate electrodes may be selected from a wide range of conducting materials. Representative examples for a top gate device include a thin (preferably <10 nm) metal for adhesion to the substrate (e.g. chromium, titanium) followed by a working metal (e.g. gold, silver, copper), a metal alloy or a metal compound (e.g. indium tin oxide). Alternatively a conductive polymer may be used instead of the two layered approach using metals. Preferably the source, drain and gate electrodes are metal. More preferably the source and drain electrodes comprise a bi-layer of chromium and gold. Preferably the gate electrode is aluminium.

The insulating layer is preferably a dielectric. Representative examples of suitable dielectrics include polytetrafluoroethylene (PTFE), perfluoro cyclo oxyaliphatic polymer (CYTOP), perfluoroalkoxy polymer resin (PFA), fluorinated ethylene-propylene (FEP), polyethylenetetrafluoroethylene (ETFE), polyvinylfluoride (PVF), polyethylenechlorotrifluoroethylene (ECTFE), polyvinylidene fluoride (PVDF), polychlorotrifluoroethylene (PCTFE), perfluoro elastomers (FFKM) such as Kalrez (RTM) or Tecnoflon (RTM), fluoro elastomers such as Viton (RTM), perfluoropolyether (PFPE) and a polymer of tetrafluoroethylene, hexafluoropropylene and vinylidene fluoride (THV). Fluorinated polymers are an attractive choice for the dielectric, particularly in the field of organic thin film transistors (OTFTs), because they possess a number of favourable properties including: (i) excellent spin coating properties, for instance: (a) wetting on a wide variety of surfaces; and (b) film formation, with the option of doing multi-layer coatings; (ii) chemical inertness; (iii) quasi-total solvent orthogonality: consequently, the risk of the organic semiconductor being dissolved by the solvent used for spin-coating the dielectric is minimal; and (iv) high hydrophobicity: this can be advantageous because it results in low water uptake and low mobility of ionic contaminants in the fluorinated polymer dielectric (low hysteresis).

Preferred devices and methods of the present invention have one or more of the following characteristics:

Substrate: Glass surface with chrome adhesion layer

Source and drain electrodes: Gold

Source and drain electrode thickness:5 to 200 nm

Electrode surface modifying compound: partially fluorinated fullerene

Channel length: less than 20 microns, e.g. 10 or 5 microns

Semiconducting layer thickness: 60 to 80 nm

Insulating layer: RIFE

Insulating layer thickness: 50 to 500 nm

Gate electrode: Aluminium

Gate electrode thickness: 20 to 300 nm

Organic devices obtainable by the method of the invention are characterised by the lateral distribution of non-polymeric semiconductors in the semiconducting layer. In particular the non-polymeric semiconductors are distributed homogeneously in the semiconducting layer in the direction parallel to the surface of the electrodes and in particular to the surface treated with surface modifying compound. This is achieved by the methods of the present invention wherein the solution used to deposit the semiconducting layer comprises a mixture of non-polymeric compounds of different molecular weights and structures which suppresses crystallisation during the deposition process. Crystallisation therefore occurs rapidly and homogeneously during the heating step to remove solvent which mimimises or prevents vertical and significant crystal growth.

In short channel length (<20 μm) devices contact resistance can contribute a significant proportion to the total channel resistance in the device. The higher the contact resistance in the device, the higher the proportion of the applied voltage is dropped across the source and drain contacts and, as a result, the lower the bias across the channel region is achieved. A high contact resistance has the effect of a much lower current level being extracted from the device due to the lower bias applied across the channel region, and hence lower device mobility. The blends and solutions of the present invention may improve the lateral distribution of non-polymeric semiconductors in the semiconducting layer and thereby reduce contact resistance. This is advantageous, especially in devices with short channel lengths.

The further advantage achieved using the blends and solutions of the present invention is a wider processing window. Thus the blends of the present invention can be dissolved in a wider range of solvents and successfully deposited therefrom. Additionally the solutions of the present invention may be deposited in a wider range of conditions (e.g. spin speeds and times) in order to achieve a target film thickness.

### BRIEF DESCRIPTION OF THE DRAWINGS

FIG. 1 is a schematic of a typical top gate thin film transistor;

FIG. 2 is a schematic of a typical bottom gate thin film transistor;

FIG. 3a shows a plot of saturation mobility (cm²/Vs) obtained for top gate, bottom contact thin film transistors made with a semiconducting layer prepared with a 4 component blend of the present invention using different drying temperatures and direct drying and on the secondary y-axis shows standard deviation, plotted as a proportion of the average mobility, at each channel length; and

FIG. 3b shows a plot of saturation mobility (cm²/Vs) obtained for top gate, bottom contact thin film transistors made with a semiconducting layer prepared with a 4 component blend of the present invention using different drying temperatures and delayed drying and on the secondary y-axis shows standard deviation, plotted as a proportion of the average mobility, at each channel length.

### DETAILED DESCRIPTION OF THE INVENTION

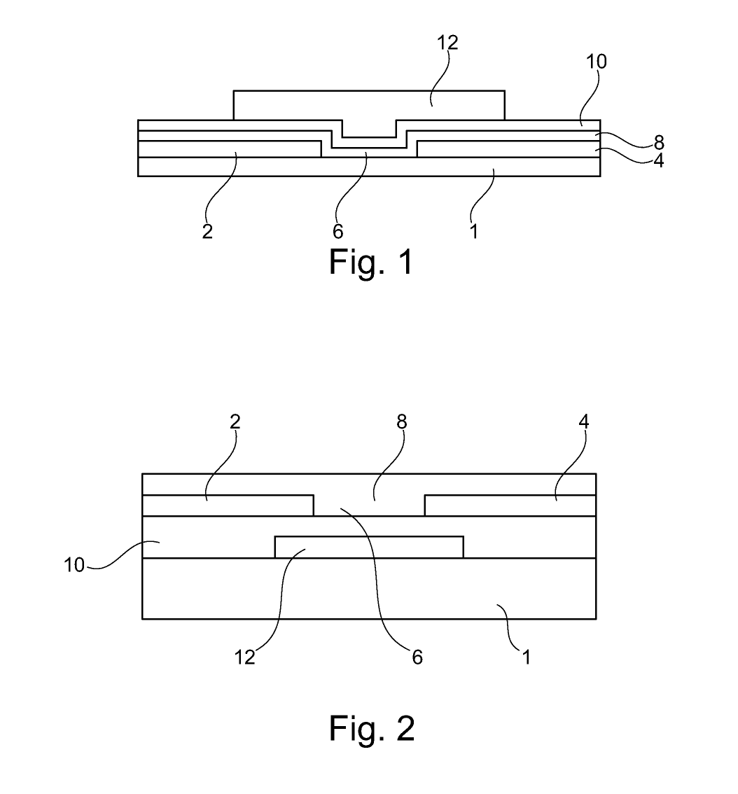

Referring to FIG. 1, it shows a schematic of a top gate thin film transistor. The structure may be deposited on a substrate 1 and comprises source and drain electrodes 2, 4 which are spaced apart with a channel region 6 located therebetween. An organic semiconductor 8 is deposited in the channel region 6 and may extend over at least a portion of the source and drain electrodes 2, 4. An insulating layer 10 of dielectric material is deposited over the organic semiconductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

FIG. 2 shows a schematic of a bottom gate thin film transistor. In FIG. 2 like reference numerals have been used for corresponding parts to FIG. 1. The bottom-gate structure illustrated in FIG. 2 comprises a gate electrode 12 deposited on a substrate 1 with an insulating layer 10 of dielectric material deposited thereover. Source and drain electrodes 2, 4 are deposited over the insulating layer 10 of dielectric material. The source and drain electrodes 2, 4 are spaced apart with a channel region 6 located therebetween over the gate electrode. An organic semiconductor 8 is deposited in the channel region 6 and may extend over at least a portion of the source and drain electrodes 2, 4.

The conductivity of the channel of the transistors can be altered by the application of a voltage at the gate. In this way the transistor can be switched on and off using an applied gate voltage. The drain current that is achievable for a given voltage is dependent on the mobility of the charge carriers in the channel region between the source and drain electrodes. Thus, in order to achieve high drain currents with low operational voltages, organic thin film transistors must have an organic semiconductor which has highly mobile charge carriers in the channel region.

### EXAMPLES

### Materials

Toluene and tetralin were obtained from Sigma-Aldrich.

### Preparative Example for the Fabrication of Organic Thin Film Transistors

### (i) Pre-Cleaning of OTFT Substrates and Self-Assembled Monolayer (SAM) Pre-Treatments:

The first step in fabrication of the device required the pre-cleaning of the device substrates and the application of surface treatment materials on the source and drain electrodes in order to ensure that the contact resistance is minimised. The substrates consist of gold source and drain electrodes on top of a chrome adhesion layer on the glass surface (5/40 nm Cr/Au). The substrates were cleaned by oxygen plasma to ensure any residual photoresist material (used for the source-drain electrode definition) is removed.

After the plasma treatment, an electrode surface-modifying compound (C₆₀F₃₆) was applied from a solution in toluene at a concentration of 1 mM by flooding the substrate in the toluene solution for a period of 5 minutes. The solution was removed by spinning the substrate on a spin coater, then rinsing it in toluene to remove any unreacted material that had not adsorbed onto the source and drain electrodes. All of these steps were performed in air. Samples were then transported to a dry nitrogen environment and baked at 60° C. for 10 minutes to ensure the samples were dehydrated.

### (ii) Preparation and Spin-Coating of the Semiconductor Blend Solution:

The blend of non-polymeric semiconductors and polymeric semiconductor was prepared as a solution in tetralin. The blends were prepared by making a single solution of the desired concentration from the pre-weighed mixture of non-polymeric and polymeric semiconductors and the solvent mixture. The blend was prepared to a concentration of 1.8% w/v (18 mg solid per 1 ml of solvent).

Tetralin was chosen as the test solvent as tetralin solutions require a wider process window than, e.g. xylene. Properties of the solvent such as a high surface tension (>35 mN/m) and high (>200° C.) boiling point can give rise to effects such receding of the film from the edge of the substrates during deposition and or film drying steps. To overcome excessive receding of the film, spin coating conditions such as higher spin coating speeds and/or times are used but it is important that this does not impact on device performance. In this example, the processing window of a 4 component blend of the present invention (concentration of 1.8% w/v) is tested by carrying out drying the semiconducting layer in different conditions and by drying immediately versus delaying drying by 2 minutes. The latter is intended to replicate a real life manufacturing scenario wherein there is inevitably a delay between at least some of the semiconducting layer being deposited and it being dried. A broader processing window is indicated by the occurrence of high and consistent mobilities regardless of the spin coating conditions used.

The composition of the 4 component blend is shown in the table below. The polymeric semiconductor was F8-TFB as disclosed above and in WO 2010/084977. The non-polymeric semiconductors are as shown below and prepared in accordance with the methods disclosed in WO 2011/004869):

| | | % by |
|---|---|---|
| | Semiconductor | weight |
| | F8-TFB, [9,9′-dioctylfluorene-co-N-(4- | 75 |
| | butylphenyl)-diphenylamine]n | |
| (l) | 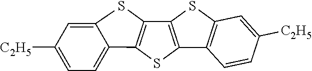 [SMILES: CCc1ccc2c(c1)sc1c2sc2c3ccc(CC)cc3sc21] | 2.3 |
| (m) | 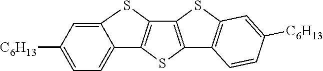 | 18.2 |
| (h) | 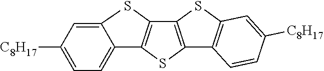 | 4.5 |

Deposition of this blend was made using a spin coater at a coating speed of 930 rpm for a period of 30 seconds. A single phase spin was used. The resulting wet film was then dried on a hot plate at a temperature of 110° C. for a period of 1 minute. The thickness of the layer was 70 nm.

(iii) Deposition of the Dielectric Layer:

A dielectric layer was then deposited by spin coating a solution of PTFE on this semiconductor film. The thickness of the dielectric layer was 350 nm.

### (iv) Deposition of the Gate Electrode:

Finally the gate electrode was deposited by thermal evaporation of 250 nm aluminium through a shadow mask to give the desired top-gate organic thin film transistor.

### COMPARATIVE EXAMPLE

A comparative device was prepared by the method described above except that the composition of the semi-conductor blend was as shown below:

| | | % by |
|---|---|---|
| | Semiconductor | weight |
| | F8-TFB, [9,9′-dioctylfluorene-co-N- | 75 |
| | (4-butylphenyl)-diphenylamine]n | |
| (m) | 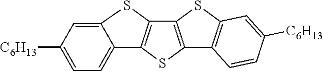 | 25 |

The above blend was prepared as a solution (1.2% w/v) in o-xylene. Deposition of this blend was made using a spin coater at a coating speed of 600 rpm fora period of 30 seconds. Drying was carried out immediately. The thickness of the layer was 87 nm.

### Device Characterisation:

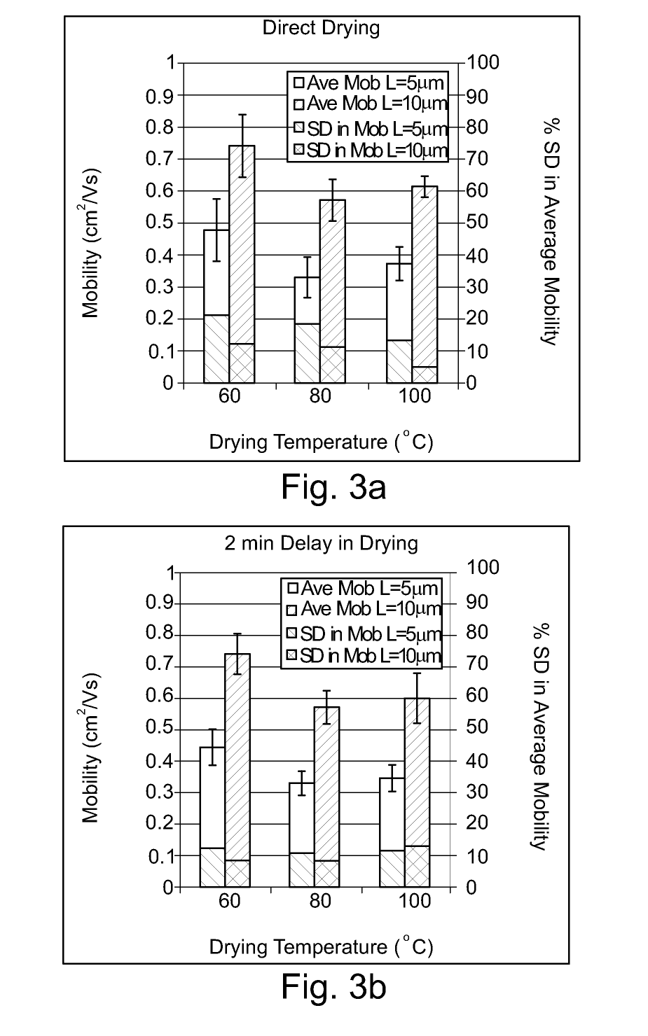

Devices produced as described above were measured in ambient conditions (no device encapsulation was used) using a Hewlett Packard 4156C semiconductor parameter analyser by measuring output and transfer device characteristics. Devices were characterised in linear and saturation regimes (drain-source bias of −3V and −40V respectively) with agate bias swept from +40 V to −40 V and reverse. The data in FIGS. 3a and 3b highlights the average in the peak saturation mobility for 5 and 10 micron channel length devices based on a drain bias of −40V with respect to the source contact. Peak saturation mobility refers to the maximum saturation mobility of the device when calculated with respect to gate bias as described above. 8 TFTs were used per channel length.

In addition to the average mobility, the deviation in mobility is also plotted above. The error bars represent +/−1 standard deviation. The standard deviation is also plotted as a proportion of the average mobility at each channel length on the secondary y-axis.

In the saturation regime the drain current is said to be “saturated” with respect to the drain bias, such that a higher drain bias does not result in a higher drain current. The mobility is a measure of how much current is delivered through the device, and it does not necessarily refer to the intrinsic mobility of the semiconductor material itself (although in many instances this is true). For example, a device with the same mobility of material in the channel region may exhibit a higher contact resistance as compared to another device, therefore exhibiting a lower “device” mobility.

The average saturation mobilities of the comparative devices with channel lengths of 5 and 10 microns were both 0.1 cm²/Vs.

FIGS. 3a and 3b highlight the device performance and uniformity of performance of devices fabricated using a blend of the present invention. The devices of the invention consistently achieve at least three-fold higher average saturation mobilities than the comparative device. Without wishing to be bound by theory, the improved mobility is thought to be due to the improved lateral homogeneity achieved with the blends and solutions of the invention.

At short channel lengths, the devices of the invention also achieve consistent peak saturation mobilities regardless of the drying temperature and drying regime (direct or delayed) used. First the level of mobility is fairly consistent whether drying occurs at 60, 80 or 100° C. Second for each replicate device prepared under each condition, the mobility range observed was narrow. This is clear from the fact that the standard deviation as a proportion of average mobility for both channel lengths and at all drying temperatures is less than 10%. Third a comparison of the data in FIG. 3a with the data in FIG. 3b shows that a delay of 2 minutes in the drying of the semiconducting layer, which is intended to replicate a real life manufacturing situation, does not significantly change the average peak mobilities achieved at each temperature or the repeatability of the results.

These results shows that devices prepared according to the present invention have a broad processing window. This allows for processing conditions to be varied to, e.g. achieve different film thicknesses, without impacting on the device performance.

1. A blend for preparing a semiconducting layer of an organic electronic device comprising:
(i) a polymer;
(ii) a first non-polymeric semiconductor;
(iii) a second non-polymeric semiconductor; and
(iv) a third non-polymeric semiconductor.

2. (canceled)

3. The blend as claimed in claim 1, wherein said second non-polymeric semiconductor has a higher molecular weight than said first non-polymeric semiconductor.

4. The blend as claimed in claim 1, wherein said third non-polymeric semiconductor has a higher molecular weight than said second non-polymeric semiconductor.

5. The blend as claimed in claim 1, wherein said first, second and third non-polymeric semiconductors are of formula (I): 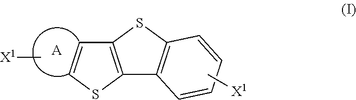
wherein A is a phenyl group or a thiophene group, said phenyl group or thiophene group optionally being fused with a phenyl group or a thiophene group which is unsubstituted or substituted with at least one group of formula X¹ and/or fused with a group selected from the group consisting of a phenyl group, a thiophene group, and a benzothiophene group, any of said phenyl, thiophene and benzothiophene groups being unsubstituted or substituted with at least one group of formula X¹; and
each group X¹ is the same or different and is (i) selected from the group consisting of unsubstituted or substituted straight, branched or cyclic alkyl groups having from 1 to 20 carbon atoms, alkoxy groups having from 1 to 12 carbon atoms, amino groups that are unsubstituted or substituted with one or two alkyl groups having from 1 to 8 carbon atoms, each of which is the same or different, amido groups, silyl groups, and alkenyl groups having from 2 to 12 carbon atoms, or (ii) a polymerisable or reactive group selected from the group consisting of halogens, boronic acids, diboronic acids and esters of boronic acids and diboronic acids, alkenyl groups having from 2 to 12 carbon atoms, and stannyl groups.

6. The blend as claimed in claim 1, wherein each of said first, second and third non-polymeric semiconductors is of formula (Ia): 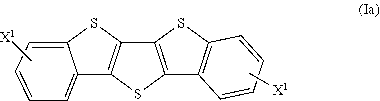
wherein each group X¹ is the same or different and is selected from the group consisting of unsubstituted or substituted straight, branched or cyclic alkyl groups having from 1 to 20 carbon atoms, alkoxy groups having from 1 to 12 carbon atoms, amino groups that are unsubstituted or substituted with one or two alkyl groups having from 1 to 8 carbon atoms, each of which is the same or different, amido groups, silyl groups, and alkenyl groups having from 2 to 12 carbon atoms.

7. The blend as claimed in claim 6, wherein each of said first, second and third non-polymeric semiconductors is of formula (Iai): 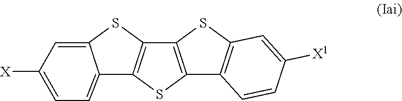
wherein each group X¹ is the same or different and is selected from the group consisting of unsubstituted or substituted straight, branched or cyclic alkyl groups having from 1 to 20 carbon atoms, alkoxy groups having from 1 to 12 carbon atoms, amino groups that are unsubstituted or substituted with one or two alkyl groups having from 1 to 8 carbon atoms, each of which is the same or different, amido groups, silyl groups, and alkenyl groups having from 2 to 12 carbon atoms.

8. The blend as claimed in claim 6, wherein each group X¹ is an unsubstituted or substituted straight, branched or cyclic alkyl group having from 1 to 20 carbon atoms.

9-10. (canceled)

11. The blend as claimed in claim 6, wherein within each non-polymeric semiconductor each group X¹ is identical and is a group of the formula CₙH₂ₙ₊₁ wherein n is an integer between 1 and 16.

12. The blend as claimed in claim 11, wherein n₁ is the integer n for the X¹ groups of the first non-polymeric semiconductor, n₂ is the integer n for the X¹ groups of the second non-polymeric semiconductor, and n₃ is the integer n of the X¹ groups of the third non-polymeric semiconductor, wherein n(l) is the lowest integer of n₂ and n₃, n(m) is a middle integer between n₁ and n₃, and n(h) is the highest integer of n₁ and n₂, and wherein the difference between n(l) and n(h) is at least 4, the difference between n(l) and n(m) is at least 2, and/or the difference between n(m) and n(h) is at least 1.

13-14. (canceled)

15. The blend as claimed in claim 1, wherein said second non-polymeric semiconductor is:

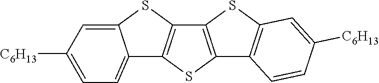

16. The blend as claimed in claim 1, wherein said first non-polymeric semiconductor is selected from the group consisting of:

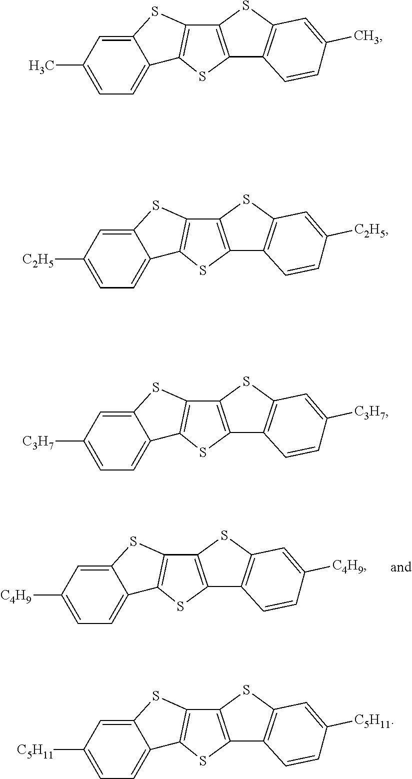

17. The blend as claimed in claim 16, wherein said first non-polymeric semiconductor is:

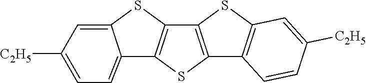 [SMILES: CCc1ccc2c(c1)sc1c2sc2c3ccc(CC)cc3sc21]

18. The blend as claimed in claim 1, wherein said third non-polymeric semiconductor is selected from the group consisting of:

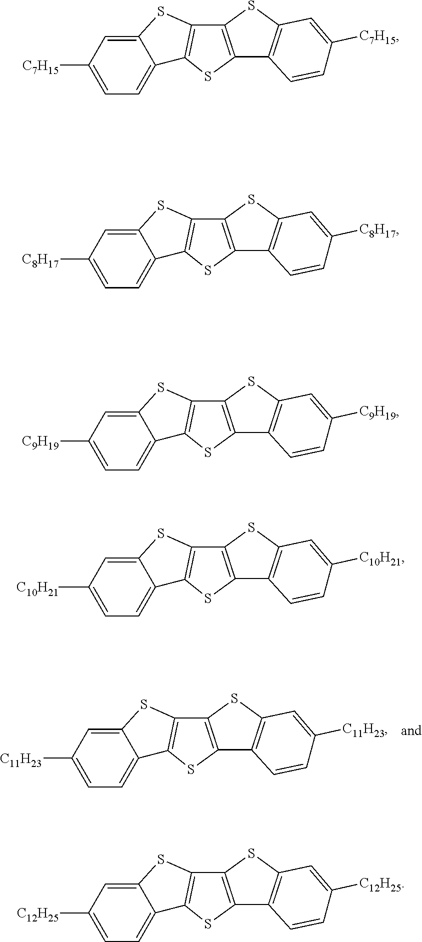

19. The blend as claimed in claim 18, wherein said third non-polymeric semiconductor is:

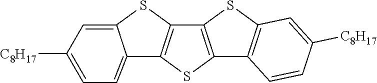

20. The blend as claimed in claim 1, wherein said first non-polymeric semiconductor is: 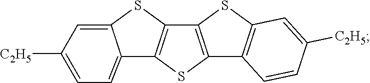 [SMILES: CCc1ccc2c(c1)sc1c2sc2c3ccc(CC)cc3sc21]
said second non-polymeric semiconductor is: 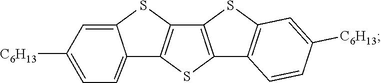
and said third non-polymeric semiconductor is:

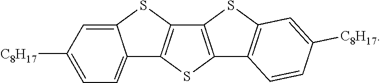

21. The blend as claimed in claim 1, wherein the weight ratio of said first non-polymeric semiconductor to said second non-polymeric semiconductor is in the range of 1:5 to 1:20, and/or wherein the weight ratio of said second non-polymeric semiconductor to said third non-polymeric semiconductor is in the range of 8:1 to 2:1, and/or wherein the weight ratio of said first non-polymeric semiconductor to said third non-polymeric semiconductor is in the range of 1:1 to 1:4.

22-23. (canceled)

24. The blend as claimed in claim 1, wherein said polymer is a polymeric semiconductor.

25. The blend as claimed in claim 24, wherein said polymeric semiconductor comprises a repeat unit of formula (II): 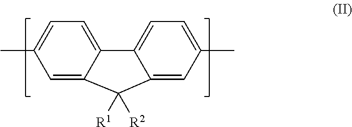
wherein R¹ and R² are the same or different and each is selected from the group consisting of hydrogen, an alkyl group having from 1 to 16 carbon atoms, an aryl group having from 5 to 14 carbon atoms, and a 5- to 7-membered heteroaryl group containing from 1 to 3 sulfur atoms, oxygen atoms, nitrogen atoms and/or selenium atoms, said aryl group or heteroaryl group being unsubstituted or substituted with one or more substituents selected from the group consisting of an alkyl group having from 1 to 16 carbon atoms and an alkoxy group having from 1 to 16 carbon atoms;
and a repeat unit of formula (III): 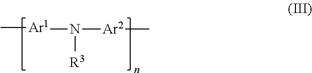
wherein Ar¹ and Ar² are the same or different and each is selected from the group consisting of an aryl group having from 5 to 14 carbon atoms and a 5- to 7-membered heteroaryl group containing from 1 to 3 sulfur atoms, oxygen atoms and/or nitrogen atoms, said aryl group or heteroaryl group being unsubstituted or substituted with one or more substituents selected from the group consisting of an alkyl group having from 1 to 16 carbon atoms and an alkoxy group having from 1 to 16 carbon atoms;
R³ is an alkyl group having from 1 to 8 carbon atoms or a phenyl group which is unsubstituted or substituted with an alkyl group having from 1 to 8 carbon atoms;
and n is an integer greater than or equal to 1.

26. The blend as claimed in claim 25, wherein said polymeric semiconductor is F8-TFB [9,9′-dioctylfluorene-co-N-(4-butylphenyl)-diphenylamine]ₙ wherein n is greater than 100.

27-41. (canceled)
